(19) United States
(12) Patent Application Publication
(10) Pub. No.: US 2007/0117534 A1
(43) Pub. Date: May 24, 2007

(54) Combination measurement device and lamp

(76) Inventor: Cheng-Chung Pai, Taichung Hsien (TW)

Correspondence Address: KIRSCHSTEIN, OTTINGER, ISRAEL;& SCHIFFMILLER, P.C., 489 FIFTH AVENUE, NEW YORK, NY, 10017, US

(21) Appl. No.: 11/435,407

(22) Filed: May 17, 2006

(30) Foreign Application Priority Data
Nov. 21, 2005 (TW) 094140808

(51) Int. Cl. H05K 11/00

(52) U.S. Cl. 455/344; 455/350

(57) ABSTRACT

A combination measurement device and lamp includes a housing unit, a measurement device, a light source unit, and a power source unit. The measurement device is disposed in the housing unit and in proximity to an upper side surface of the housing unit, and includes a measurement body having a display face visible through a window in the housing unit. The light source unit is attached to and disposed in front of the housing unit. The power source unit is disposed within the housing unit, and is coupled electrically to the light source unit.

### CROSS-REFERENCE TO RELATED APPLICATION

This application claims priority of Taiwanese Application No. 094140808, filed on Nov. 21, 2005.

### BACKGROUND OF THE INVENTION

1. Field of the Invention

This invention relates to a measurement device and a lamp for a bicycle, and more particularly to a combination measurement device and lamp.

2. Description of the Related Art

A conventional bicycle may be mounted with a lamp on a handle unit for purposes of illumination or to alert the others of the bicycle rider's presence. A measurement device, such as a stopwatch or a speedometer/odometer for measuring respectively the lapsed time and the distance traveled by the bicycle may also be mounted on the bicycle. When a bicycle is mounted with both a lamp and a measurement device, however, the following drawbacks are encountered:
(1) A process for mounting such separate members to the bicycle is troublesome.
(2) The lamp and the measurement device are disposed fixedly on a frame of the bicycle, and therefore cannot be removed from the frame for other utilizations.

### SUMMARY OF THE INVENTION

The object of this invention is to provide a combination measurement device and lamp that can be mounted to a handle unit of a bicycle and that can overcome the above-mentioned disadvantages associated with the prior art.

According to this invention, a combination measurement device and lamp includes a housing unit, a measurement device unit, a light source unit, and a power source unit. The measurement device unit is disposed in the housing unit and in proximity to an upper side surface of the housing unit, and includes a measurement body having a display face visible through a window in the housing unit. The light source unit is attached to and disposed in front of the housing unit. The power source unit is disposed within the housing unit, and is coupled electrically to the light source unit. A support is connected removably to a lower side surface of the housing unit. In one embodiment, the support has a configuration that can be connected removably to a handgrip of a bicycle. As such, the combination measurement device and lamp can be mounted to the bicycle with ease by simply assembling the support to the bicycle. Furthermore, the combination measurement device and lamp can be removed from the bicycle for other utilizations, e.g., as a desk lamp on a desk.

### BRIEF DESCRIPTION OF THE DRAWINGS

These and other features and advantages of this invention will become apparent in the following detailed description of the preferred embodiments of this invention, with reference to the accompanying drawings, in which:

FIG. 1 is a fragmentary exploded perspective view of the first preferred embodiment of a combination measurement device and lamp according to this invention, in which a support is removed;

FIG. 2 is a fragmentary top view of the first preferred embodiment;

FIG. 3 is a fragmentary bottom view of the first preferred embodiment;

FIG. 4 is a fragmentary sectional view of the first preferred embodiment when a light source unit is disposed in a normal position;

FIG. 5 is a schematic side view of the first preferred embodiment;

FIG. 6 is a fragmentary sectional view of the first preferred embodiment, illustrating a first position of the light source unit;

FIG. 7 is a fragmentary sectional view of the first preferred embodiment, illustrating a second position of the light source unit;

FIG. 8 is a fragmentary side view of the second preferred embodiment of a combination measurement device and lamp according to this invention, illustrating a first modified support;

FIG. 9 is a fragmentary side view of the third preferred embodiment of a combination measurement device and lamp according to this invention, illustrating a second modified support;

FIG. 10 is a fragmentary side view of the fourth preferred embodiment of a combination measurement device and lamp according to this invention, illustrating a third modified support; and

FIG. 11 is a fragmentary exploded perspective view of the fifth preferred embodiment of a combination measurement device and lamp according to this invention, illustrating a modified light source unit.

### DETAILED DESCRIPTION OF THE PREFERRED EMBODIMENTS

Before the present invention is described in greater detail in connection with the preferred embodiments, it should be noted that similar elements and structures are designated by like reference numerals throughout the entire disclosure.

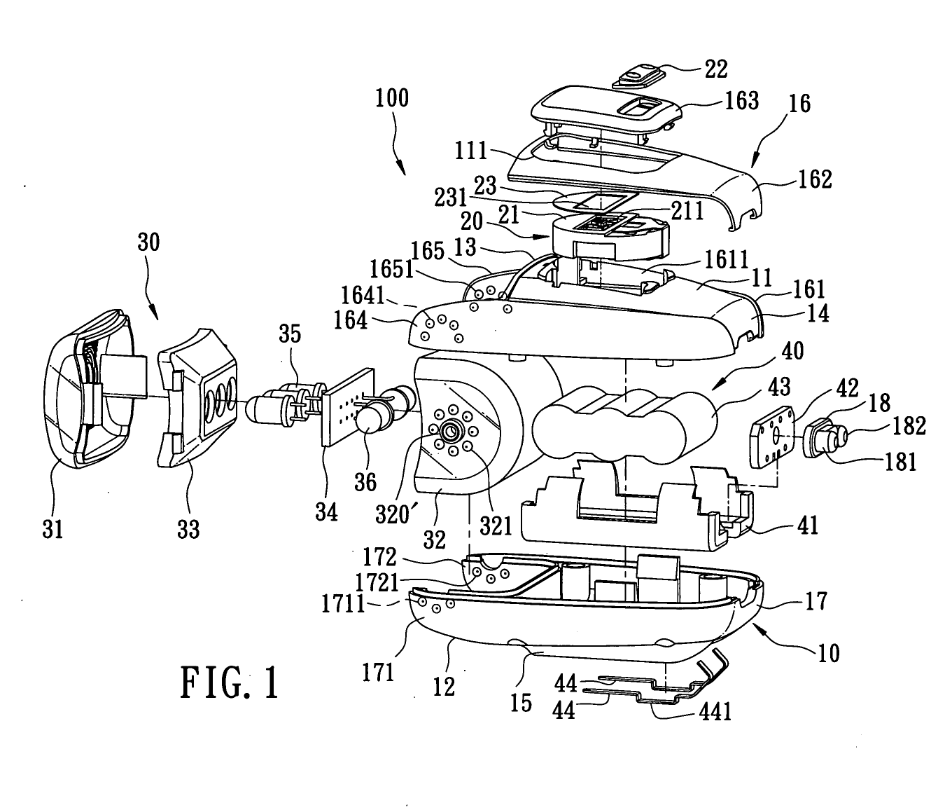

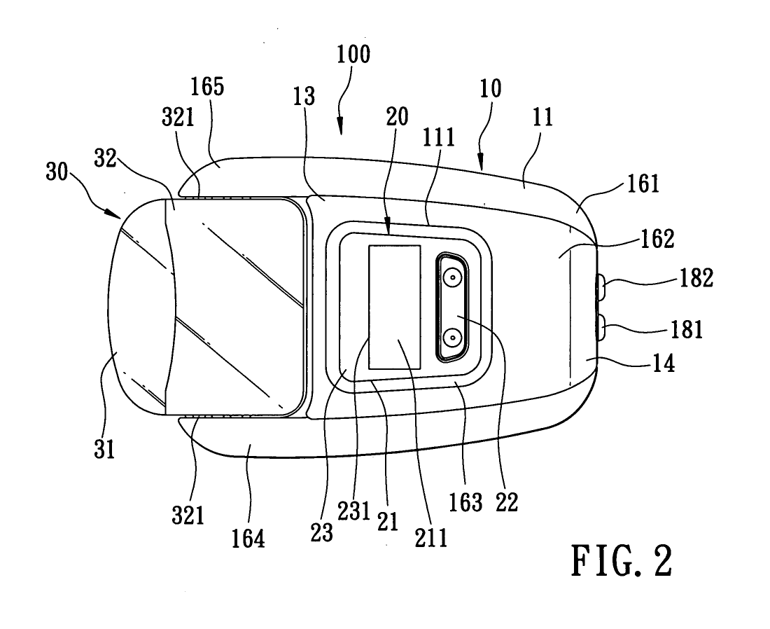

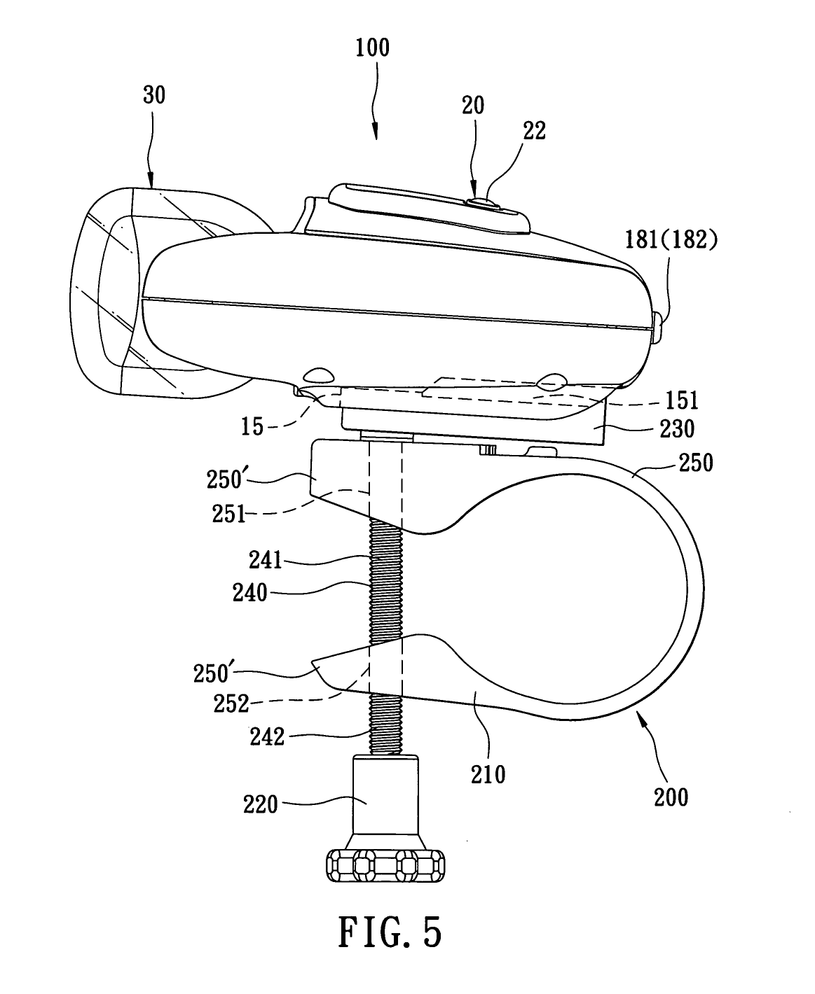

Referring to FIGS. 1 to 5, the first preferred embodiment of a combination measurement device and lamp according to this invention includes an operation assembly 100 and a support 200.

The operation assembly 100 includes a housing unit 10, a measurement device 20 configured as a stopwatch, a light source unit 30, and a power source unit 40.

The housing unit 10 has upper and lower side surfaces 11, 12, front and rear end portions 13, 14, and a connecting portion 15 disposed on the lower side surface 12. The upper side surface 11 is formed with a window 111. In this embodiment, the housing unit 10 includes upper and lower housing halves 16, 17 that are interconnected fixedly. The upper housing half 16 has a top surface constituting the upper side surface 11 of the housing unit 10. The lower housing half 17 has a bottom surface constituting the lower side surface 12 of the housing unit 10. The housing unit 10 further includes a control knob unit 18 disposed on the rear end portion 14 thereof. The control knob unit 18 includes a pair of first and second control knobs 181, 182.

The connecting portion 15 is formed with two parallel slots 151 each having an open end at the rear end portion 14.

The upper housing half 16 includes a primary housing portion 161, an auxiliary housing portion 162, and a transparent panel 163. The auxiliary housing portion 162 is connected fixedly to the primary housing portion 161 so as to define an accommodating space 1611 therebetween. The window 111 is formed in the auxiliary housing portion 162, and is in spatial communication with the accommodating space 1611. The transparent panel 163 is disposed fixedly within the window 111.

The primary housing portion 161 of the upper housing portion 16 includes a pair of left and right pivot arms 164, 165 that extend forwardly from two opposite sides thereof. The lower housing 17 also includes a pair of left and right pivot arms 171, 172 that extend forwardly from two opposite sides thereof and that are aligned respectively with the left and right pivot arms 164, 165 of the primary housing portion 161. Each of the left and right pivot arms 164, 165, 171, 172 has an inner side surface that is formed with a plurality of semispherical grooves 1641, 1651, 1711, 1721 arranged along a semicircle. The left pivot arms 164, 171 cooperate to define a pivot hole. The right pivot arms 165, 172 also cooperate to define a pivot hole.

The measurement device 20 includes a measurement body 21, an operation key 22, and an annular pad 23. The measurement body 21 is disposed within the accommodating space 1611 in the housing unit 10 and in proximity to the upper side surface 11 of the housing unit 10, and has a display face 211 visible through the transparent panel 163 disposed in the window 111 in the housing unit 10. The operation key 22 is disposed on the transparent panel 163, and is operable to contact the measurement body 21. The annular pad 23 is disposed between the measurement body 21 and the transparent panel 163, and has an opening 231 aligned with the display face 211 of the measurement body 21. Alternatively, the measurement device 20 may be a speedometer or a calorimeter.

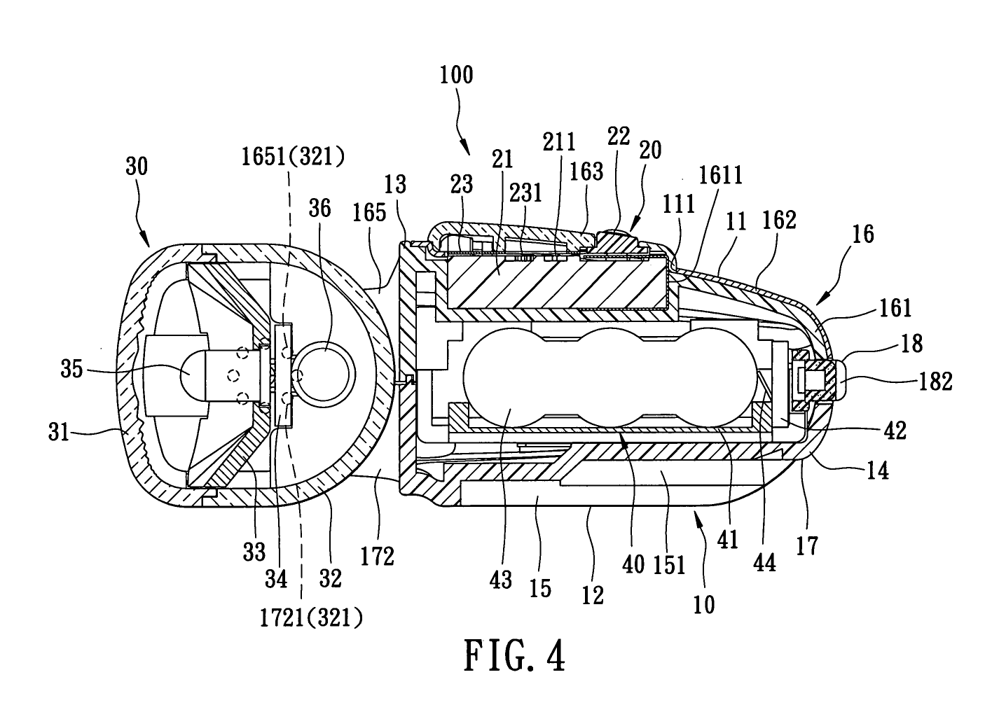

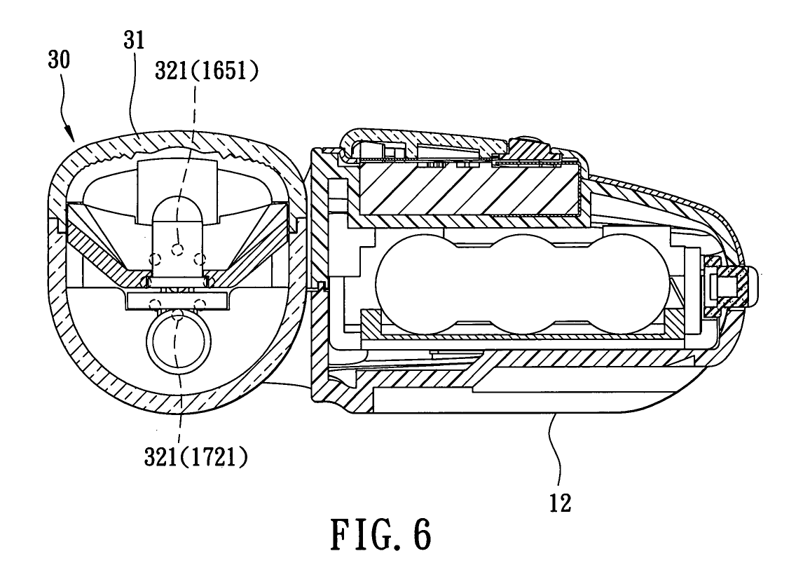

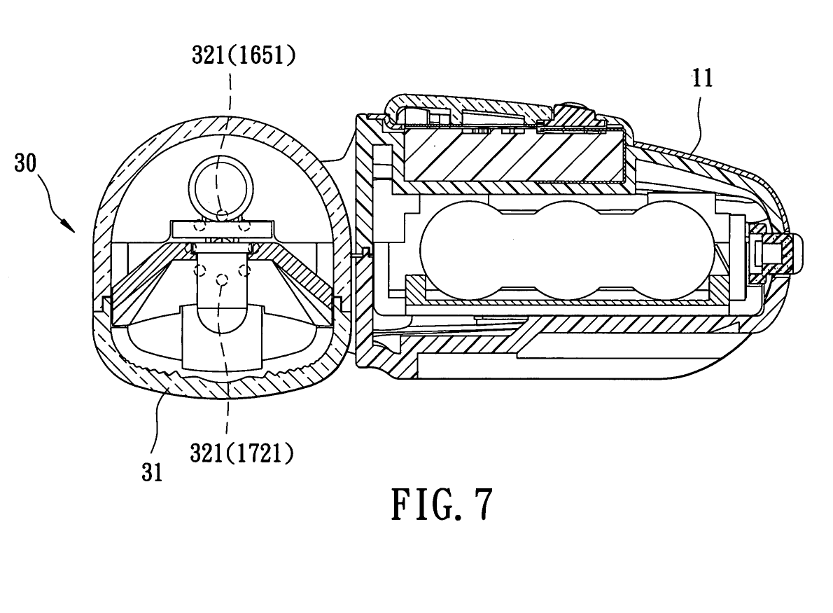

The light source unit 30 is disposed pivotally between the left and right pivot arms 164, 165, 171, 172 of each of the upper and lower housing halves 16, 17, and includes a pair of transparent front and rear light shades 31, 32, a reflection plate 33, a circuit board 34, a plurality of first lamps 35, and a plurality of second lamps 36. The rear light shade 32 is disposed behind and connected fixedly to the front light shade 31, and is disposed pivotally between the left and right pivot arms 164, 165, 171, 172 of the upper and lower housing halves 16, 17. In this embodiment, the rear light shade 32 has two opposite side surfaces each formed with a pivot pin element 320′ and a plurality of semispherical projections 321 disposed around the pivot pin element 320′ and arranged along a circle. The pivot holes defined by the upper and lower housing halves 16, 17 engage respectively the pivot pin elements 320′ of the rear light shade 32. The projections 321 of the rear light shade 32 engage respectively the grooves 1641, 1651, 1711, 1721 in the left and right pivot arms 164, 165, 171, 172 of the housing unit 10. As such, an indexed rotation of the light source unit 30 can be performed. In this embodiment, the light source unit 30 is rotatable by 45° at a time. As such, the light source unit 30 is rotatable relative to the housing unit 10 from the normal position shown in FIG. 4 to a first position shown in FIG. 6 whereat the first lamps 35 direct light upwardly, and to a second position shown in FIG. 7 whereat the first lamps 35 direct light downwardly. The reflection plate 33 is disposed between the front and rear light shades 31, 32. The circuit board 34 is disposed between the reflection plate 33 and the rear light shade 32. The first lamps 35 are disposed between the front light shade 31 and the reflection plate 33, and are in electrical connection with the circuit board 34. The second lamps 36 are disposed between the rear light shade 32 and the reflection plate 33, and are in electrical connection with the circuit board 34. In this embodiment, the first lamps 35 are configured as white light-emitting diodes, and the second lamps 36 are configured as red light-emitting diodes. The first control knob 181 of the control knob unit 18 is operable to activate the first lamps 35. The second control knob 182 of the control knob unit 18 is operable to activate the second lamps 36.

The power source unit 40 is disposed within the housing unit 10, and is coupled electrically to the circuit board 34 of the light source unit 30. The power source unit 40 includes a battery seat 41 disposed between the upper and lower housing halves 16, 17, a circuit board 42 disposed on the battery seat 41, a rechargeable battery set 43 disposed within the battery seat 41 and coupled electrically to the circuit board 42, and two charging plates 44 fastened to the lower housing half 17. The first and second control knobs 181, 182 can be operated to contact the circuit board 42. Each of the charging plates 44 has an electrode 441 that extends outwardly of the housing unit 10 via the corresponding slot 151.

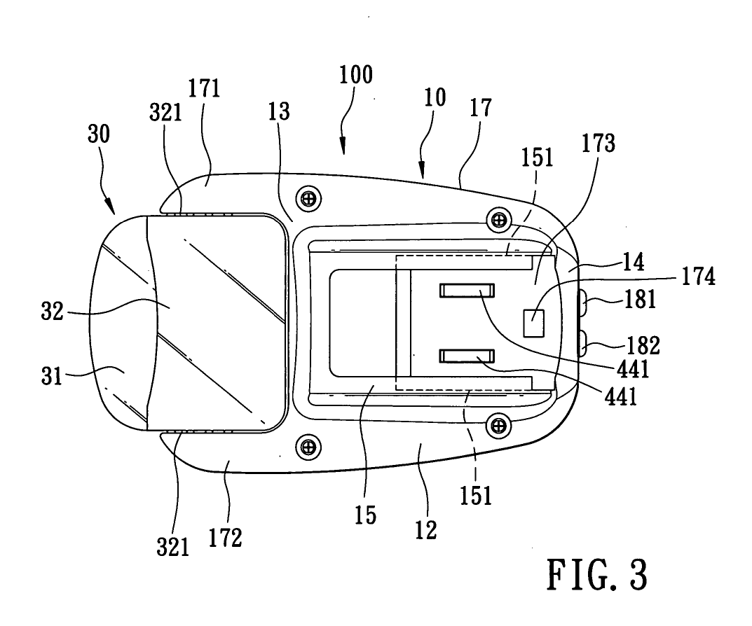

The support 200 includes a connecting portion 230, a upright threaded rod 240, a C-shaped retaining ring 250, and a knob 220. The connecting portion 230 is formed with an integral dovetail tongue (not shown) fitted within a dovetail groove 173 (see FIG. 3) in the housing unit 10, and a positioning recess (not shown) engaging a positioning protrusion 174 (see FIG. 3) so as to prevent removal of the dovetail tongue from the dovetail groove 173. The positioning protrusion 174 can be removed forcibly from the positioning recess. As such, the connecting portion 230 is connected removably to the lower side surface 12 of the housing unit 10. The threaded rod 240 has an upper end journalled on the connecting portion 230, as well as a pair of left-hand and right hand-threaded portions 241, 242. The C-shaped retaining ring 250 has two ends 250′ formed with threaded holes 251, 252 engaging respectively the left-hand and right-hand threaded portions 241, 242. When the threaded rod 240 is rotated in a direction, the ends 250′ of the C-shaped ring 250 move toward each other. When the threaded rod 240 is rotated in an opposite direction, the ends 250′ of the C-shaped retaining ring 250 move away from each other. The knob 220 is connected fixedly to a lower end of the threaded rod 240, and is operable so as to sleeve the C-shaped retaining ring 250 fixedly on a bicycle (not shown), that is, on a handgrip of a handle unit of the bicycle.

As such, the combination measurement device and lamp of this invention can be mounted to the bicycle with ease by simply assembling the support 200 to the bicycle. Furthermore, the combination measurement device and lamp can be removed from the bicycle for other utilizations, e.g., as a desk lamp on a desk.

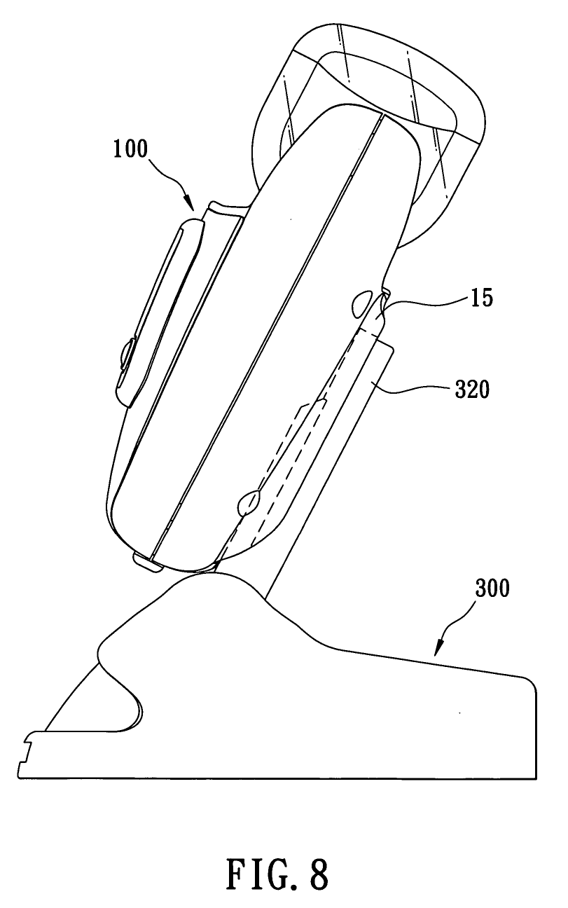

FIG. 8 shows a first modified support 300 that is configured as a charging seat for charging the battery seat 43 (see FIG. 1) when the connecting portion 15 of the operating assembly 100 is connected removably to a connecting portion 320 of the support 300.

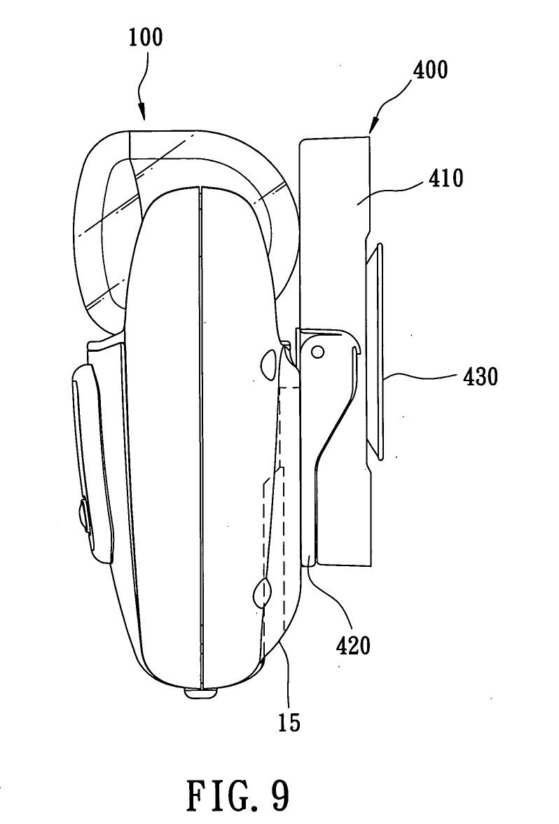

FIG. 9 shows a second modified support 400 that includes a supporting body 410, a connecting portion 420 connected fixedly to the supporting body 410 and connected removably to the connecting portion 15 of the operation assembly 100, and a suction cup 430 fastened to the supporting body 410 for attachment to a smooth surface.

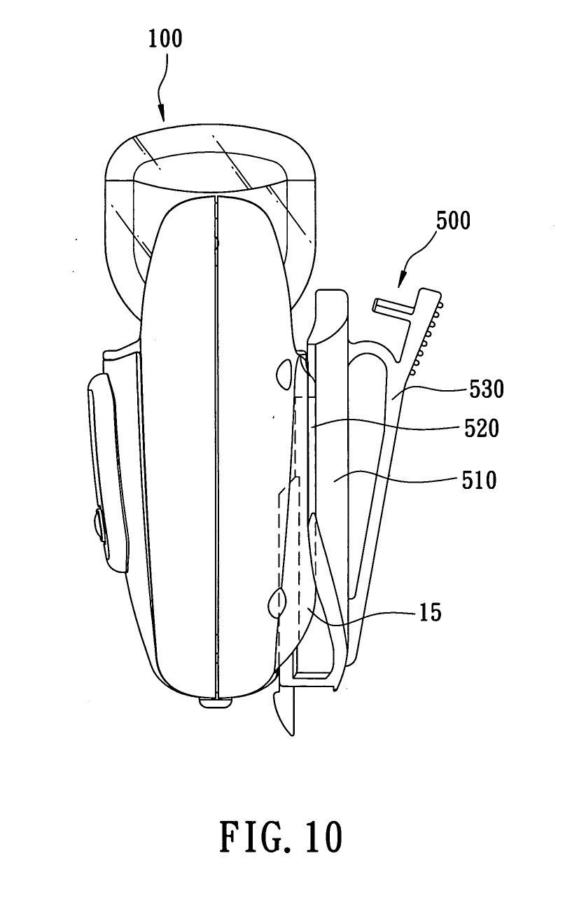

FIG. 10 shows a third modified support 500 that includes a supporting body 510, a connecting portion 520 connected fixedly to the supporting body 510 and connected removably to the connecting portion 15 of the operation assembly 100, and a clamp portion 530 fastened to the supporting body 510. The clamp portion 530 can be fastened to a pocket on a pair of pants, a belt, etc.

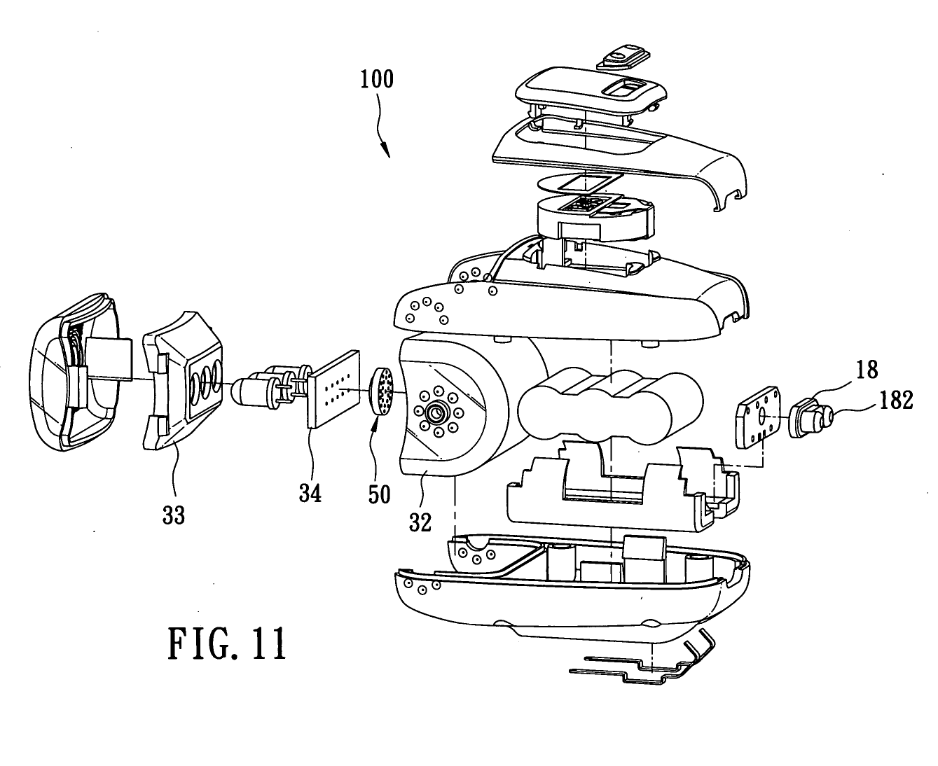

FIG. 11 shows a modified light source unit 30, which is similar in construction to the first preferred embodiment except that the second lamps 36 are replaced with a buzzer 50. In this embodiment, the second control knob 182 can be operated so as to control operation of the buzzer 50.

With this invention thus explained, it is apparent that numerous modifications and variations can be made without departing from the scope and spirit of this invention. It is therefore intended that this invention be limited only as indicated by the appended claims.

I claim:

1. A combination measurement device and lamp comprising:
a housing unit having upper and lower side surfaces, as well as front and rear end portions, said upper side surface being formed with a window;
a measurement device disposed in said housing unit and in proximity to said upper side surface of said housing unit and including a measurement body that has a display face visible through said window in said housing unit;
a light source unit attached to and disposed in front of said front end portion of said housing unit; and
a power source unit disposed within said housing unit and coupled electrically to said light source unit.

2. The combination measurement device and lamp as claimed in claim 1, wherein said light source unit is rotatable relative to said housing unit.

3. The combination measurement device and lamp as claimed in claim 1, wherein said housing unit includes upper and lower housing halves interconnected fixedly, said upper housing half having a top surface constituting said upper side surface of said housing unit, said lower housing half having a bottom surface constituting said lower side surface of said housing unit, said upper housing half including a primary housing portion, an auxiliary housing portion connected fixedly to said primary housing portion so as to define an accommodating space therebetween, and a transparent panel disposed fixedly within said window in said housing unit such that said display face of said measurement body is visible through said transparent panel, said measurement body being disposed within said accommodating space in said housing unit, said window being formed in said auxiliary housing portion and being in spatial communication with said accommodating space.

4. The combination measurement device and lamp as claimed in claim 3, wherein said measurement device further includes an operation key disposed on said transparent panel and operable to contact said measurement body, an annular pad disposed between said measurement body and said transparent panel and having an opening aligned with said display face of said measurement body.

5. The combination measurement device and lamp as claimed in claim 3, wherein each of said upper and lower housing halves of said housing unit further includes a pair of left and right pivot arms extending respectively and forwardly from two opposite sides of a corresponding one of said upper and lower housing halves, said light source unit being disposed pivotally between said left and right pivot arms of each of said upper and lower housing halves.

6. The combination measurement device and lamp as claimed in claim 1, wherein said light source unit includes:
a front light shade;
a rear light shade disposed behind and connected fixedly to said front light shade, said rear light shade being disposed pivotally between said left and right pivot arms of said upper and lower housing halves;
a reflection plate disposed between said front and rear light shades;
a circuit board disposed between said reflection plate and said rear light shade;
a plurality of first lamps disposed between said front light shade and said reflection plate and in electrical connection with said circuit board, said light source unit being rotatable relative to said housing unit to a first position whereat said first lamps direct light upwardly, and a second position whereat said first lamps direct light downwardly; and
a plurality of second lamps disposed between said rear light shade and said reflection plate and in electrical connection with said circuit board.

7. The combination measurement device and lamp as claimed in claim 6, wherein each of said left and right pivot arms of said upper and lower housing halves has an inner side surface that is formed with a plurality of grooves arranged along a semicircle, said rear light shade having two opposite side surfaces each formed with a plurality of projections arranged along a circle, said projections of said rear light shade engaging respectively said grooves in said left and right pivot arms of said upper and lower housing halves.

8. The combination measurement device and lamp as claimed in claim 6, wherein said housing unit further includes a control knob unit disposed on said rear end portion of said housing unit, said control knob unit including a first control knob for controlling operation of said first lamps, and a second control knob for controlling operation of said second lamps.

9. The combination measurement device and lamp as claimed in claim 6, wherein said first lamps are configured as white light-emitting diodes, and said second lamps are configured as red light-emitting diodes.

10. The combination measurement device and lamp as claimed in claim 3, wherein said power source unit includes a battery seat disposed between said upper and lower housing halves, a circuit board disposed on said battery seat, and a battery set disposed within said battery seat and coupled electrically to said circuit board.

11. The combination measurement device and lamp as claimed in claim 10, wherein said battery set is configured as a rechargeable battery.

12. The combination measurement device and lamp as claimed in claim 1, further comprising a buzzer, and said light source unit includes:
a front light shade;
a rear light shade disposed behind and connected fixedly to said front light shade, said rear light shade being disposed pivotally between said left and right pivot arms of said upper and lower housing halves;
a reflection plate disposed between said front and rear light shades;
a circuit board disposed between said reflection plate and said rear light shade; and
a plurality of first lamps disposed between said front light shade and said reflection plate and in electrical connection with said circuit board, said light source unit being rotatable relative to said housing unit to a first position whereat said first lamps direct light upwardly, and a second position whereat said first lamps direct light downwardly, said buzzer being disposed between said rear light shade and said reflection plate and in electrical connection with said circuit board.

13. The combination measurement device and lamp as claimed in claim 12, wherein said housing unit further includes a control knob unit disposed on said rear end portion of said housing unit, said control knob unit including a first control knob for controlling operation of said first lamps, and a second control knob for controlling operation of said buzzer.

14. The combination measurement device and lamp as claimed in claim 1, further comprising a support connected removably to said lower side surface of said housing unit.

15. The combination measurement device and lamp as claimed in claim 14, wherein said support includes:
a connecting portion connected removably to said housing unit;
an upright threaded rod having an upper end journalled on said connecting portion, as well as a pair of left-hand and right-hand threaded portions; and
a C-shaped retaining ring having two ends formed with threaded holes engaging respectively said left-hand and right-hand threaded portions of said threaded rod such that, when said threaded rod is rotated in a direction, said ends of said C-shaped retaining ring move toward each other, and when said threaded rod is rotated in an opposite direction, said ends of said C-shaped retaining ring move away from each other.

16. The combination measurement device and lamp as claimed in claim 15, wherein said support further includes a knob connected fixedly to a lower end of said threaded rod.

17. The combination measurement device and lamp as claimed in claim 14, wherein said power source unit includes a battery seat disposed between said upper and lower housing halves, a circuit board disposed on said battery seat, and a battery set disposed within said battery seat and coupled electrically to said circuit board.

18. The combination measurement device and lamp as claimed in claim 17, wherein said battery set is configured as a rechargeable battery.

19. The combination measurement device and lamp as claimed in claim 18, wherein
said power source unit further includes two charging plates fastened to said housing unit, each of said charging plates having an electrode extending outwardly of said housing unit; and
said support is configured as a charging seat for charging said battery set when said housing unit is connected to said support.

20. The combination measurement device and lamp as claimed in claim 14, wherein said support includes a connecting portion connected removably to said housing unit, and a suction cup fastened to said connecting portion.

21. The combination measurement device and lamp as claimed in claim 14, wherein said support includes a connecting portion connected removably to said housing unit, and a clamp portion fastened to said connecting portion.
